(19) United States
(12) Patent Application Publication
(10) Pub. No.: US 2025/0107337 A1
(43) Pub. Date: Mar. 27, 2025

(54) DISPLAY PANEL

(71) Applicant: Electronics and Telecommunications Research Institute, Daejeon (KR)

(72) Inventors: Byoung-Hwa KWON, Daejeon (KR); Chan-mo KANG, Daejeon (KR); Hyungwoo SUH, Daejeon (KR); Jin Wook SHIN, Daejeon (KR); YOONSUNG YOO, Daejeon (KR); Hyunsu CHO, Daejeon (KR); Chul Woong JOO, Daejeon (KR); Sukyung CHOI, Daejeon (KR)

(21) Appl. No.: 18/618,163

(22) Filed: Mar. 27, 2024

(30) Foreign Application Priority Data
Sep. 21, 2023 (KR) 10-2023-0126542

(51) Int. Cl. H10K 59/122; H10K 59/38; H10K 59/80

(52) U.S. Cl. CPC H10K 59/122; H10K 59/8792; H10K 59/38

(57) ABSTRACT

Provided is a display panel including a base substrate, a display element layer, and a light control layer, wherein the display element layer includes a first electrode, a second electrode, a light-emitting layer and a first pixel definition layer, the light control layer includes a second pixel definition layer, and a light control pattern including quantum dots, a bottom surface of the first pixel definition layer has a first width in a first direction, the first pixel definition layer has a first height in a second direction, a bottom surface of the second pixel definition layer has a second width in the first direction, the second pixel definition layer has a second height in the second direction, and a first aspect ratio calculated by dividing the first height by the first width is smaller than a second aspect ratio calculated by dividing the second height by the second width.

### CROSS-REFERENCE TO RELATED APPLICATIONS

This U.S. non-provisional patent application claims priority under 35 U.S.C. § 119 of Korean Patent Application No. 10-2023-0126542, filed on Sep. 21, 2023, the entire contents of which are hereby incorporated by reference.

### BACKGROUND

The present disclosure herein relates to a display panel, and more particularly, to a display panel including a quantum dot (QD)-organic light emitting diode (QLED).

An organic light emitting diode (OLED) is an element configured to convert electrical energy into light by applying an electric field to an organic thin film composed of an organic material, and may be used as a pixel to implement a self-emissive display device having excellent characteristics.

A quantum dot (QD) is a semiconductor light emitting material of nanometer size, and may be used as a component to implement a display device having excellent color characteristics. Combining such QD material technology with OLED technology makes it possible to implement a QD-OLED display device having excellent performance to which all the advantages of the QLED and the QD are applied.

### SUMMARY

The present disclosure provides a display panel having improved color reproducibility and optical characteristics.

The present disclosure also provides a display panel with improved process efficiency and applicable to a stretchable element.

The technical objects of the present disclosure are not limited to the above-mentioned ones, and the other unmentioned technical objects will become apparent to those skilled in the art from the following description.

An embodiment of the inventive concept provides a display panel including: a base substrate; a display element layer on the base substrate; and a light control layer on the display element layer, wherein the display element layer may include: a first electrode; a second electrode on the first electrode; a light-emitting layer disposed between the first electrode and the second electrode; and a first pixel definition layer configured to expose at least a portion of the first electrode on the base substrate, the light control layer may include: a second pixel definition layer; and a light control pattern disposed between portions of the second pixel definition layer and including quantum dots, a bottom surface of the first pixel definition layer may have a first width in a first direction parallel to a top surface of the base substrate, the first pixel definition layer may have a first height in a second direction vertical to the top surface of the base substrate, a bottom surface of the second pixel definition layer may have a second width in the first direction, the second pixel definition layer may have a second height in the second direction, the first pixel definition layer may have a tapered shape in which the width in the first direction decreases along the second direction, and a first aspect ratio calculated by dividing the first height by the first width may be smaller than a second aspect ratio calculated by dividing the second height by the second width.

In an embodiment, each the first width and the second width may be about 50 μm or smaller.

In an embodiment, the second height may be double or more than the first height.

In an embodiment, the first height may be about 1 to about 3 μm, and the second height may be about 4 to about 15 μm.

In an embodiment, the light-emitting layer may emit source light, and the source light may be blue light or a mixture of red light and green light.

In an embodiment, the first pixel definition layer may vertically overlap at least a portion of the second pixel definition layer.

In an embodiment, a slope of a side surface of the first pixel definition layer may be smaller than that of a side surface of the second pixel definition layer.

In an embodiment, the display panel may further include an encapsulation layer disposed between the display element layer and the light control layer.

In an embodiment of the inventive concept, a display panel includes: a base substrate; a display element layer on the base substrate; and a display element layer on the circuit element layer; and a light control layer on the display element layer, wherein the display element layer may include: a first electrode; a second electrode on the first electrode; a light-emitting layer disposed between the first electrode and the second electrode; and a first pixel definition layer configured to cover the circuit element layer and expose at least a portion of the first electrode, the light control layer may include: a second pixel definition layer; and a light control pattern disposed between portions of the second pixel definition layer and including quantum dots, each of the first pixel definition layer and the second pixel definition layer may have a width decreasing in a direction parallel to a top surface of the base substrate along a direction away from the top surface of the base substrate, a side surface of the first pixel definition layer may have a first slope, a side surface of the second pixel definition layer may have a second slope, and the first slope may be smaller by at least about 20° than the second slope.

In an embodiment, the first slope may be about 30 to about 50°.

In an embodiment, the second slope may be about 70 to about 100°.

In an embodiment, the display panel may further include at least one among a hole injection layer, a hole transport layer, an electron transport layer, or an electron injection layer disposed between the first electrode and the second electrode.

In an embodiment, the circuit element layer may include a transistor, a buffer layer, and an insulation layer.

In an embodiment, the base substrate may include glass, and a layer facing the base substrate may not include glass.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a schematic cross-sectional view of the structure of the display panel according to an embodiment of the inventive concept;

FIG. 2 is a cross-sectional view of the structure of the display panel in FIG. 1;

FIG. 3 is an enlarged view of a portion CU in FIG. 2; and

FIGS. 4A to 4D are cross-sectional views for showing manufacturing processes of a display panel according to an embodiment of the inventive concept.

### DETAILED DESCRIPTION

The embodiments of the present invention will now be described with reference to the accompanying drawings for sufficiently understating a configuration and effects of the inventive concept. However, the inventive concept is not limited to the following embodiments and may be embodied in different ways, and various modifications may be made thereto. The embodiments are just given to provide complete disclosure of the inventive concept and to provide thorough understanding of the inventive concept to those skilled in the art. In the accompanying drawings, the sizes of the elements may be greater than the actual sizes thereof, for convenience of description, and the scales of the elements may be exaggerated or reduced.

A display panel 1000 according to an embodiment of the inventive concept may include a base substrate 100, a circuit element layer 110, a display element layer 120, an encapsulation layer 130, and an optical control layer 140 that are sequentially laminated. The display panel 1000 may include emission areas PXA-B, PXA-G, and PXA-R, and a non-emission area NPXA according to areas. The emission areas PXA-B, PXA-G, and PXA-R may be areas from which light generated in the display element layer 120 is emitted.

In the specification, a first direction D1 is defined as one direction parallel to the top surface of the base substrate 100. A second direction D2 is defined as one direction parallel to the top surface of the base substrate 100 and vertical to the first direction D1. A third direction D3 is defined as one direction vertical to the top surface of the base substrate 100. The plane defined by the first direction D1 and the second direction D2 may be a display surface with an image displayed thereon. The third direction D3 may be defined as a direction in which the image is provided to a user.

The base substrate 100 may be a member providing a base surface on which a circuit element layer 110 is disposed. The base substrate 100 may include glass. As for the display panel 1000 according to an embodiment of the inventive concept, a layer facing the base substrate 100 may not include glass.

The circuit element layer 110 may be disposed on the base substrate 100. The circuit element layer 110 may include a plurality of transistors (not shown), a buffer layer (not shown) and insulation layers (not shown). Each of the transistors may include a control electrode, an input electrode, and an output electrode. For example, the circuit element layer 110 may include a switching transistor and a driving transistor for driving a display element layer 120.

The display element layer 120 may be disposed on the circuit element layer 110. The display element layer 120 may include a first pixel definition layer 300, first electrodes AE, a second electrode CE over the first electrodes AE, and a common layer CML disposed between the first electrodes AE and the second electrode CE.

Each portion of the first pixel definition layer 300 may be spaced apart from each other in the first direction D1 on the circuit element layer 110 to define the emission areas PXA-B, PXA-G, and PXA-R and the non-emission area NPXA. In other words, the non-emission area NPXA may correspond to the first pixel definition layer 300 in the third direction D3, and cover the circuit element layer 110 on the base substrate 100. The first pixel definition layer 300 may include openings 300s and configured to expose at least portions of the first electrodes AE. The openings 300s may be substantially the same as the sides of the openings in the first pixel definition layer 300.

The first pixel definition layer 300 may be provided with a polymer resin. For example, the first pixel definition layer 300 may include a polyacrylate-based resin or a ployimide-based resin. The first pixel definition layer 300 may include a black pigment or a black dye.

The first electrodes AE may be disposed on the circuit element layer 110. The first electrodes AE may be anodes or cathodes. The first electrodes AE may be transmissive electrodes or semi-transmissive electrodes. The second electrode CE may be disposed on the first electrodes AE. The second electrode CE may be a transmissive electrode or a semi-transmissive electrode. When the first electrodes AE are the cathodes, the second electrode CE is an anode, and when the first electrodes AE are the anodes, the second electrode CE is a cathode.

The common layer CML may be disposed between the first electrodes AE and the second electrode CE. Although not shown, the common layer CML may include at least one among a hole injection layer, a hole transport layer, a light emitting layer, an electron transport layer, or an electron injection layer.

The hole injection layer, the hole transport layer, the light emitting layer, the electron transport layer, or the electron injection layer may be disposed in common in the emission areas PXA-B, PXA-G, and PXA-R, and the non-emission area NPXA, and may be sequentially laminated.

The light emitting layer may generate source light, and the source light may be blue light. In other words, the light emitting layer may generate light in a wavelength band of about 410 nm to about 480 nm. In the specification, the source light may be referred to as first light. Alternatively, according to some embodiments of the inventive concept, the source light may be a mixture of blue light and green light.

The encapsulation layer 130 may be disposed on the second electrode CE to cover the display element layer 120. The encapsulation layer 130 may include a first inorganic encapsulation layer 130a disposed on the second electrode CE, an organic encapsulation layer 130b disposed on the first inorganic encapsulation layer 130a, and a second inorganic encapsulation layer 130c disposed on the organic encapsulation layer 130b. The first and second inorganic encapsulation layers 130a and 130c may include an inorganic material, and the organic encapsulation layer 130b may include an organic material. The first and third inorganic encapsulation layers 130a and 130c may protect the display element layer 120 from moisture/oxygen. The organic encapsulation layer 130b may protect the common layer CML from foreign matters such as dust particles.

The light control layer 140 may be disposed on the encapsulation layer 130. The light control layer 140 may include a second pixel definition layer 400, first to third light control patterns 500a, 500b, and 500c, first and second insulation patterns 141 and 142, and first to third color filters CF1, CF2, and CF3.

Each portion of the second pixel definition layer 400 may be spaced apart from each other in the first direction D1 on the encapsulation layer 130. The second pixel definition layer 400 may be disposed corresponding to the non-emission area NPXA, and the aforementioned first pixel definition layer 300 may vertically overlap at least a portion of the second pixel definition layer 400. The second pixel definition layer 400 may divide the first to third light control patterns 500a, 500b, and 500c and prevent a light leakage phenomenon. The second pixel definition layer 400 may be a black matrix. The second pixel definition layer 400 may include an organic light blocking material or an inorganic light blocking material including a black pigment or a black dye.

The first to third light control patterns 500a, 500b, and 500c may be spaced apart in the first direction D1 on the encapsulation layer 130 by the portions of the second pixel definition layer 400. In other words, the first to third light control patterns 500a, 500b, and 500c may be disposed between the portions of the second pixel definition layer 400.

The first light control pattern 500a may transmit first light generated in the display element layer 120. The second light control pattern 500b may convert the first light to second light. The third light control pattern 500c may convert the first light to third light. The first light may be blue light as described above. The second and third light may be green and red light respectively. In other words, the first light control pattern 500a may transmit the blue light, the second light control pattern 500b may convert the blue light to the green light, and the third light control pattern 500c may convert the blue light to the red light.

The first light control pattern 500a may include scatterers SP and a first base resin BR1. The second light control pattern 500b may include scatterers SP, a second base resin BR2, and first quantum dots QD1. The third light control pattern 500a may include scatterers SP, a third base resin BR3, and second quantum dots QD2.

The scatterers SP may be inorganic particles. For example, the scatterers SP may include at least one of TiO₂, ZnO, Al₂O₃, SiO₂, or a hollow silica. The scatterers SP may include one of TiO₂, ZnO, Al₂O₃, SiO₂, or a hollow silica, or a mixture of two or more materials selected from among TiO₂, ZnO, Al₂O₃, SiO₂, or a hollow silica.

Each of the first to third base resins BR1, BR2, and BR3 are a medium in which the first and second quantum dots QD1 and QD2 are dispersed, and typically be composed of various resin compositions which may be referred to as binders. For example, each of the base resins BR1, BR2, and BR3 may be an acrylic resin, a urethane resin, a silicone resin, an epoxy resin, or the like.

Each of the first and second quantum dots QD1 and QD2 may be a group II-VI compound, a group III-V compound, a group IV-VI compound, a group IV element, a group IV compound, or semiconductor nanocrystals selectable from a combination thereof.

The group II-VI compound may be selected from a group consisting of: a binary compound selected from a group consisting of CdSe, CdTe, ZnS, ZnSe, ZnTe, ZnO, HgS, HgSe, HgTe, MgSe, MgS, and a mixture thereof; a ternary compound selected from a group consisting of AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; or a quaternary compound selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group I-III-VI compound may be selected from among: a ternary compound selected from a group consisting of AgInS₂, CuInS₂, AgGaS₂, CuGaS₂, and a mixture thereof, or a quaternary compound among AgInGaS₂, CuInGaS₂ or the like.

The group III-V compound includes one selected from a group consisting of: a binary compound selected from a group consisting of GaN, GaP, GaAs, GaSb, AlN, AIP, AlAs, AlSb, InN, InP, InAs, InSb, and a mixture thereof; a ternary compound selected from a group consisting of GaNP, GaNAs, GaNSb, GaPAs, GaPSb, AlNP, AlNAs, AlNSb, AlPAs, AlPSb, InNP, InNAs, InNSb, InPAs, InPSb, GaAINP, and a mixture thereof; or a quaternary compound selected from a group consisting of GaAINAs, GaAINSb, GaAlPAs, GaAlPSb, GaInNP, GalnNAs, GalnNSb, GalnPAs, GalnPSb, InAINP, InAINAs, InAINSb, InAIPAs, InAlPSb, and a mixture thereof. Meanwhile, the group III-V compound may further include a group II metal. For example, InZnP or the like may be selected as the group III-II-V compound.

The group IV-VI compound may be selected from a group consisting of: a binary compound selected from a group consisting of SnS, SnSe, SnTe, PbS, PbSe, PbTe, and a mixture thereof; a ternary compound selected from a group consisting of SnSeS, SnSeTe, SnSTe, PbSeS, PbSeTe, PbSTe, SnPbS, SnPbSe, SnPbTe, and a mixture thereof; or a quaternary compound selected from a group consisting of SnPbSSe, SnPbSeTe, SnPbSTe, and a mixture thereof. The group IV element may be selected from a group consisting of Si, Ge, and a mixture thereof. The Group IV compound may be a binary compound selected from a group consisting of SiC, SiGe, and a mixture thereof.

Here, the binary compound, the ternary compound, or the quaternary compound may be present inside a particle in uniform concentrations, or present in the same particle in a state where the concentration distribution is partially divided into different states. In addition, the binary compound, the ternary compound, or the quaternary compound may have a core-shell structure in which one quantum dot surrounds another quantum dot. The interface between the core and the shell may have a concentration gradient in which the concentration of elements present in the shell becomes lower toward the core.

In some embodiments, the first and second quantum dots QD1 and QD2 may have a core-shell structure including the core including the aforementioned nano-crystals and the shell enclosing the core. The shell of the quantum dots QD1 and QD2 may serve as a protection layer for preventing the core from being chemically modified to maintain the semiconductor characteristics and/or as a charging layer for giving the electrophoretic characteristics to the quantum dots. The shell may be a single layer or a multilayer. The interface between the core and the shell may have a concentration gradient in which the concentration of elements present in the shell becomes lower toward the core. An example shell of the first and second quantum dots QD1 and QD2 may be provided by a metal or a non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO or the like, or a ternary compound such as MgAl₂O₄, CoFe₂O₄, NiFe₂O₄, CoMn₂O₄ or the like, but the embodiment of the inventive concept is not limited thereto.

An example semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb or the like, but the embodiment of the inventive concept is not limited thereto.

The quantum dots QD1 and QD2 may have a full width of half maximum (FWHM) of an emission wavelength spectrum of about 45 nm or shorter, preferably about 40 nm or shorter, more preferably about 30 nm or shorter, and, in this range, the color purity or color gamut may be improved.

In addition, the shapes of the quantum dots QD1 and QD2 are not particularly limited to those typically used in this art, but, more specifically, a spherical, pyramidal, or multi-arm type, or a cubic nano particle, a nano tube, a nanowire, a nano fiber, a nano-planar particle or the like may be used.

The first and second quantum dots QD1 and QD2 may adjust the color of the emitted light according to the particle size, and accordingly, may have various emission colors including red, green, or the like. For example, the particle sizes of the first quantum dots QD1 configured to emit green light may be smaller than those of the second quantum dots QD2 configured to emit red light.

The first insulation layer 141 may be disposed on the second pixel definition layer 400 and the first to third light control patterns 500a, 500b, and 500c. The first insulation layer 141 may be an inorganic layer encapsulating the first to third light control patterns 500a, 500b, and 500c.

The first to third color filters CF1, CF2, and CF3 may be respectively disposed on the first to third light control patterns 500a, 500b, and 500c. Namely, the first to third color filters CF1, CF2, and CF3 may be respectively disposed corresponding to the first to third light control patterns 500a, 500b, and 500c. The first color filter CF1 may transmit source light. The second color filter CF2 may transmit second color light. The second color filter CF3 may transmit third color light. The first to third color filters CF1, CF2, and CF3 may reduce the reflectivity for external light.

The second insulation layer 142 may be disposed on the first to third color filters CF1, CF2, and CF3 and the first insulation layer 141. The second insulation layer 142 may serve to protect the structures in the lower layers.

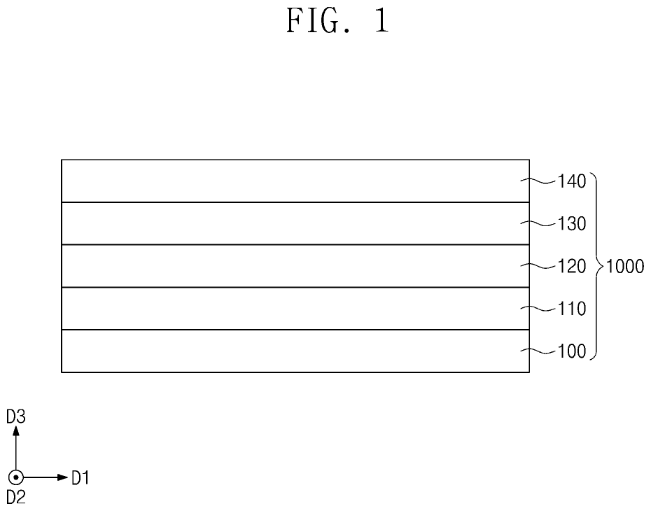

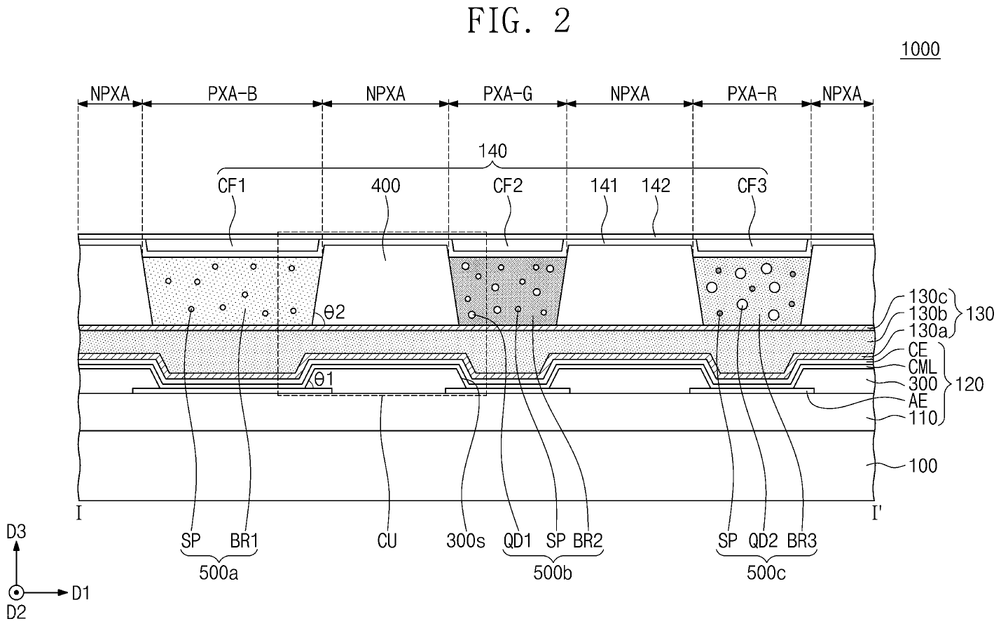

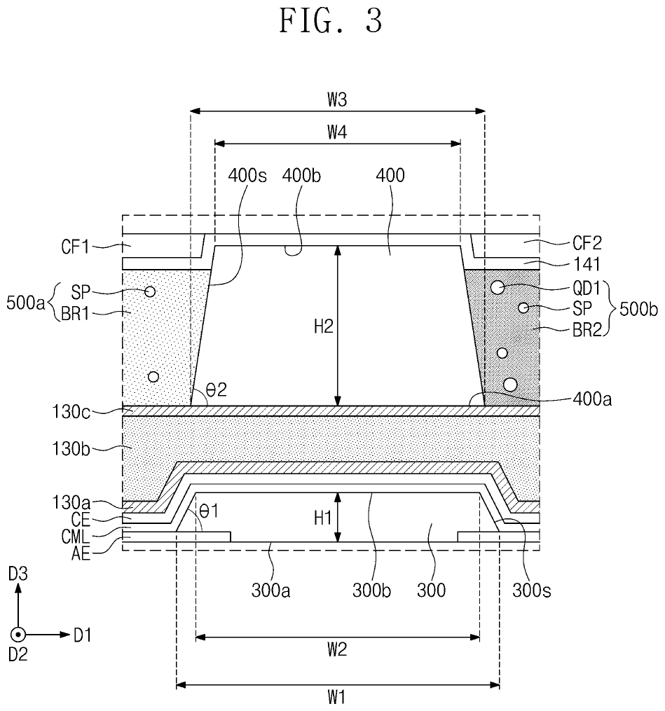

FIG. 3 is an enlarged view of a portion CU in FIG. 2. Repetitive description overlapping with FIGS. 1 and 2 will be omitted.

Referring to FIG. 3, the first pixel definition layer 300 may include a first bottom surface 300a and a first top surface 300b facing to each other. The first bottom surface 300a may have a first width W1 in the first direction D1. The first top surface 300b may have a second width W2 in the first direction D1. The second width W2 may be narrower than the first width W1. The first pixel definition layer 300 may have a first height H1 in the third direction D3. The second pixel definition layer 400 may include a second bottom surface 400a and a second top surface 400b facing to each other. The second bottom surface 400a may have a third width W3 in the first direction D1. The second top surface 400b may have a fourth width W4 in the first direction D1. The fourth width W4 may be narrower than the third width W3. The second pixel definition layer 400 may have a second height H2 in the third direction D3. The first width W1 may have substantially the same length as the third width W3. The first and third widths W1 and W3 may be about 50 μm or shorter. The length of the second height H2 may be double the length of the first height H1. For example, the first length H1 may be about 1 to about 3 μm, and the second height may be about 4 to about 15 μm. A first aspect ratio calculated by dividing the first height H1 by the first width W1 may be smaller than that calculated by dividing the second height H2 by the third width W3.

Each of the first pixel definition layer 300 and the second pixel definition layer 300 may have a tapered shape in which the width in the first direction D1 decreases along the third direction D3. Namely, each of the first pixel definition layer 300 and the second pixel definition layer 400 may has the width decreasing in a direction parallel to the top surface of the base substrate 100 along a direction away from the top surface of the base substrate 100. Although not shown in the drawing, the second pixel definition layer 400 according to some embodiments of the inventive concept may have a rectangular shape unlike the first pixel definition layer 300. According to some embodiments of the inventive concept, unlike the first pixel definition layer 300, the second pixel definition layer 400 may have the width increasing in the direction parallel to the top surface of the base substrate 100 along the direction away from the top surface of the base substrate 100.

The side surface 300s of the first pixel definition layer 300 may have a first slope θ1. The side surface 400s of the second pixel definition layer 400 may have a second slope θ2. The first slope θ1 in the specification may be an angle formed by the side surface 300s of the first pixel definition layer 300 and each of the first electrodes AE. The second slope θ2 in the specification may be an angle formed by the side surface 400s of the second pixel definition layer 400 and the second inorganic encapsulation layer 130c. The first slope θ1 may be smaller than the second slope θ2. For example, the first slope θ1 may be smaller by at least about 20° than the second slope θ2. The first slope θ1 may be about 30 to about 50°. The second slope θ2 may be about 70 to about 100°.

For the display panel 1000 according to an embodiment of the inventive concept, the first aspect ratio calculated by dividing the first height H1 of the first pixel definition layer 300 by the first width W1 may be smaller than the second aspect ratio calculated by dividing the second height H2 of the second pixel definition layer 400 by the third width W3. Namely, due to the large aspect ratio of the second pixel definition layer 400, the first and second quantum dots QD1 and QD2 disposed between the portions of the second pixel definition layer 400 may stably maintain their optical characteristics, and the lifespan of the quantum dots may be extended. As a result, the color reproducibility of the display panel 1000 may be enhanced to provide a clearer and sharper image, and the optical characteristics of the display panel 1000 may be enhanced.

In addition, the display panel 1000 according to an embodiment of the inventive concept may include the circuit element layer 110, the encapsulation layer 130, and the light control layer 140 may be laminated on the one base substrate 100. As a result, material costs may be reduced and the processes may be simplified in comparison to the existing processes in which two substrates are used. Besides, the display panel 1000 according to an embodiment of the inventive concept may use a single substrate to be applied to a stretchable device.

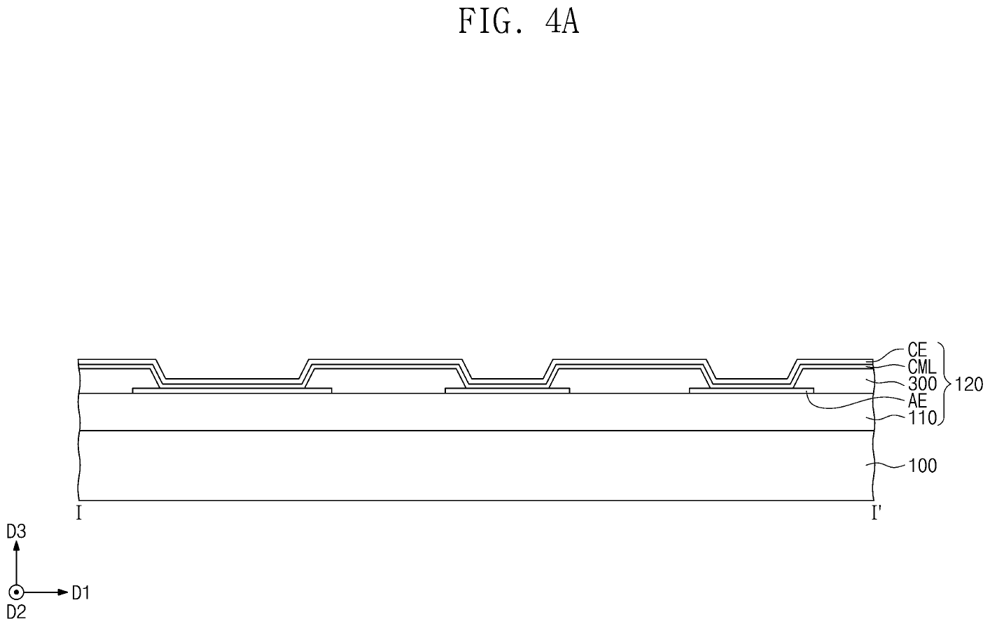

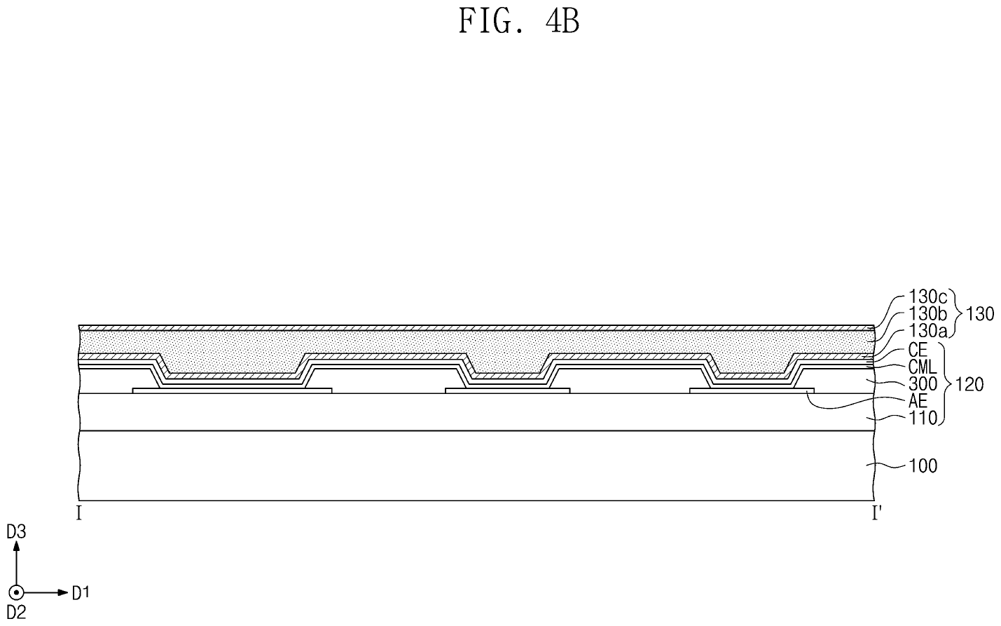

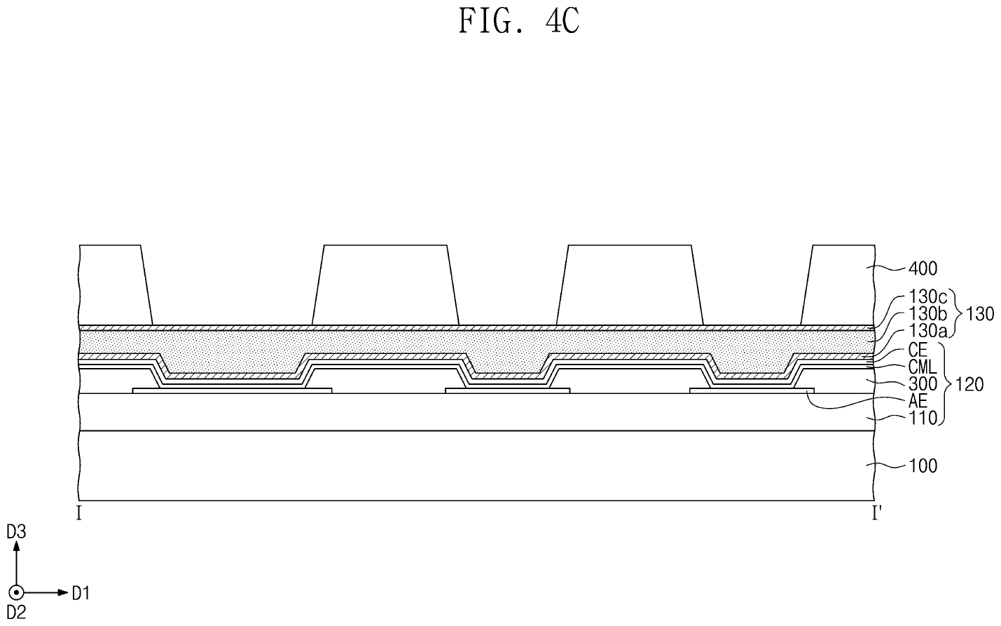

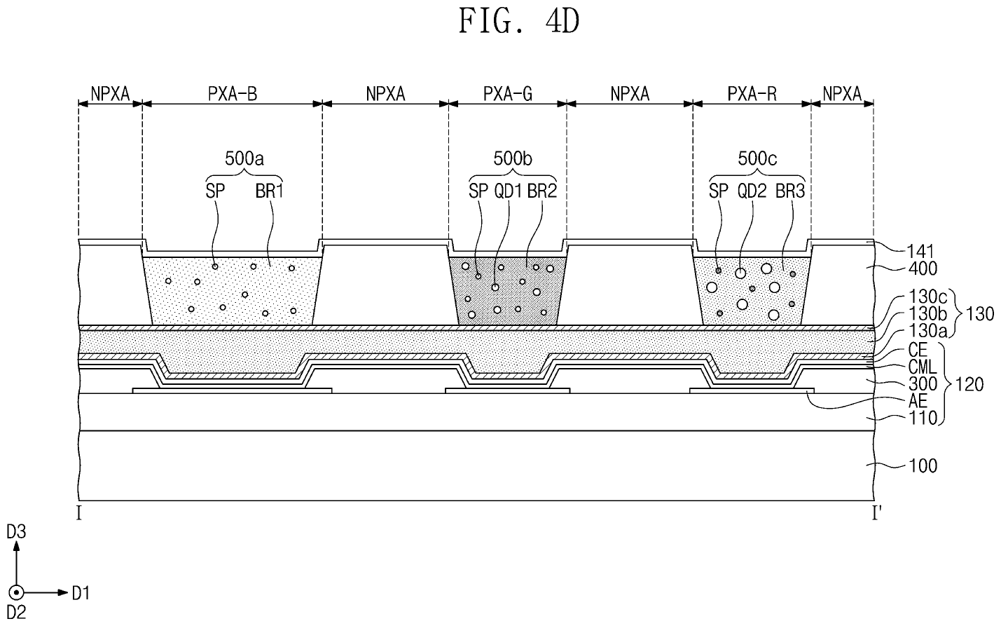

FIGS. 4A to 4D are cross-sectional views showing a display panel manufacturing process according to an embodiment of the inventive concept.

Referring to FIG. 4A, the circuit element layer 100 may be provided on the base substrate 100. Each of the first electrodes AE may be provided by applying a semi-transmissive or transmissive material on the circuit element layer 110, and then patterning the semi-transmissive or transmissive material so as to be overlapped with the emission areas PXA-B, PXA-G, and PXA-R. The first pixel definition layer 300 may be provided by applying an organic material on the first electrodes AE and then patterning the organic material so as to expose at least the portions of the first electrodes AE.

Thereafter, the common layer CML on the first pixel definition layer 300 and the second electrode CE on the common layer CML may be provided in one pattern to provide the display element layer 120.

Referring to FIG. 4B, the encapsulation layer 130 may be provided on the light emitting element layer 120. Providing the encapsulation layer 130 may include providing the first inorganic encapsulation layer 130a on the display element layer 120, providing the organic encapsulation layer 130b on the first inorganic encapsulation layer 130a, and providing the second inorganic encapsulation layer 130c on the organic encapsulation layer 130b.

Referring to FIG. 4C, the second pixel definition layer 400 may be provided on the second inorganic encapsulation layer 130c. The second pixel definition layer 400 may be provided by applying a dye and/or a pigment mixed with the base resin on the second inorganic encapsulation layer 130c and then patterning the mixture so as to overlap the non-emission area NPXA. Here, the thickness of the second pixel definition layer 400 may be thicker than that of the first pixel definition layer 300. Specifically, the thickness of the second pixel definition layer 400 may be double or more than that of the first pixel definition layer 300.

Referring to FIG. 4D, the first to third light control patterns 500a, 500b, and 500c may be provided between the portions of the second pixel definition layer 400 through an inkjet printing process. Providing the first to third light control patterns 500a, 500b, and 500c may include applying a liquid composition on corresponding spaces between the portions of the pixel definition layer 400 and curing the composition through a thermal curing process or a light curing process so as to fix the composition. Then, the insulation material is applied on the first on third light control patterns 500a, 500b, and 500c and the first insulation layer 141 may be provided through the patterning process.

Referring to FIG. 2 again, the first to third color filters CF1, CF2, and CF3 are provided on the first insulation layer 141 and the display panel 1000 shown in FIG. 2 may be completed by providing the second insulation layer 142 to cover the first insulation layer 141 and the first to third color filters CF1, CF2, and CF3.

The display panel according to the embodiments of the inventive concept may be provided using a single substrate to be applied for material cost saving, process simplification, or a stretchable element.

In addition, in the display panel according to the embodiments of the inventive concept, the aspect ratio of the second pixel definition layer is greater than that of the first pixel definition layer. As a result, the quantum dots disposed in the second pixel definition layer may maintain the stable optical characteristics, and the lifespan of the quantum dots may be extended. As the characteristics of the quantum dots are enhanced, the color reproducibility of the display panel is enhanced to provide a clearer and sharper image, and the optical characteristics of the display panel may be improved.

The exemplary embodiments of the present disclosure have been described above with reference to the accompanying drawings, but those skilled in the art will understand that the present disclosure may be implemented in another concrete form without changing the technical spirit or an essential feature thereof. Therefore, the aforementioned exemplary embodiments are all illustrative and are not restricted to a limited form.

1. A display panel comprising:
a base substrate;
a display element layer on the base substrate; and
a light control layer on the display element layer,
wherein the display element layer comprises:
a first electrode;
a second electrode on the first electrode;
a light-emitting layer disposed between the first electrode and the second electrode; and
a first pixel definition layer configured to expose at least a portion of the first electrode on the base substrate,
the light control layer comprises:
a second pixel definition layer; and
a light control pattern disposed between portions of the second pixel definition layer and comprising quantum dots,
a bottom surface of the first pixel definition layer has a first width in a first direction parallel to a top surface of the base substrate,
the first pixel definition layer has a first height in a second direction vertical to the top surface of the base substrate,
a bottom surface of the second pixel definition layer has a second width in the first direction,
the second pixel definition layer has a second height in the second direction,
the first pixel definition layer has a tapered shape in which the width in the first direction decreases along the second direction, and
a first aspect ratio calculated by dividing the first height by the first width is smaller than a second aspect ratio calculated by dividing the second height by the second width.

2. The display panel of claim 1, wherein each the first width and the second width is about 50 μm or smaller.

3. The display panel of claim 1, wherein the second height is double or more than the first height.

4. The display panel of claim 1, wherein the first height is about 1 to about 3 μm, and the second height is about 4 to about 15 μm.

5. The display panel of claim 1, wherein the light-emitting layer emits source light, and the source light is blue light or a mixture of red light and green light.

6. The display panel of claim 1, wherein the first pixel definition layer vertically overlaps at least a portion of the second pixel definition layer.

7. The display panel of claim 1, wherein a slope of a side surface of the first pixel definition layer is smaller than that of a side surface of the second pixel definition layer.

8. The display panel of claim 1, further comprising:
an encapsulation layer disposed between the display element layer and the light control layer.

9. A display panel comprising:
a base substrate;
a display element layer on the base substrate; and
a display element layer on the circuit element layer; and
a light control layer on the display element layer,
wherein the display element layer comprises:
a first electrode;
a second electrode on the first electrode;
a light-emitting layer disposed between the first electrode and the second electrode; and
a first pixel definition layer configured to cover the circuit element layer and expose at least a portion of the first electrode,
the light control layer comprises:
a second pixel definition layer; and
a light control pattern disposed between portions of the second pixel definition layer and comprising quantum dots,
each of the first pixel definition layer and the second pixel definition layer has a width decreasing in a direction parallel to a top surface of the base substrate along a direction away from the top surface of the base substrate,
a side surface of the first pixel definition layer has a first slope,
a side surface of the second pixel definition layer has a second slope, and
the first slope is smaller by at least about 20° than the second slope.

10. The display panel of claim 9, wherein the first slope is about 30 to about 50°.

11. The display panel of claim 9, wherein the second slope is about 70 to about 100°.

12. The display panel of claim 9, further comprising:
at least one among a hole injection layer, a hole transport layer, an electron transport layer, or an electron injection layer disposed between the first electrode and the second electrode.

13. The display panel of claim 9, wherein the circuit element layer comprises a transistor, a buffer layer, and an insulation layer.

14. The display panel of claim 9, wherein the base substrate comprises glass, and a layer facing the base substrate does not comprise glass.
